(19) United States
(12) Patent Application Publication
(10) Pub. No.: US 2016/0005822 A1
(43) Pub. Date: Jan. 7, 2016

(54) SELF-ALIGNED VIA FOR GATE CONTACT OF SEMICONDUCTOR DEVICES

(71) Applicant: QUALCOMM Incorporated, San Diego, CA (US)

(72) Inventors: Stanley Seungchul SONG, San Diego, CA (US); Choh Fei YEAP, San Diego, CA (US); Kern RIM, San Diego, CA (US); Zhongze WANG, San Diego, CA (US)

(21) Appl. No.: 14/321,568

(22) Filed: Jul. 1, 2014

(51) Int. Cl. H01L 29/40; H01L 29/66; H01L 29/417; H01L 29/78

(52) U.S. Cl. CPC H01L 29/401; H01L 29/78; H01L 29/66568; H01L 29/41775

(57) ABSTRACT

Systems and methods are directed to a three-terminal semiconductor device including a self-aligned via for connecting to a gate terminal Hardmasks and spacers formed over top portions and sidewall portions of a drain connection to a drain terminal and a source connection to a source terminal protect and insulate the drain connection and the source connection, such that short circuits are avoided between the source and drain connections and the self-aligned via. The self-aligned via provides a direct metal-gate connection path between the gate terminal and a metal line such as a M1 metal line while avoiding a separate gate connection layer.

### FIELD OF DISCLOSURE

Disclosed embodiments are directed to self-aligned contact formation for connecting a gate terminal of a semiconductor device with metal lines, while avoiding shorting with source and drain connections to source and drain terminals.

### BACKGROUND

Transistors formed from metal-oxide semiconductor field-effect transistor (MOS FET) structures are commonly employed in the design of semiconductor devices and integrated circuits. More specifically, complementary MOS or CMOS circuits include combinations of p-channel (or PMOS) and n-channel (NMOS) MOSFETs to implement logic gates. These MOSFETs are conventionally three terminal devices, which includes a drain terminal, a source terminal, and a gate terminal. The gate terminal is formed on a polysilicon or “poly” layer, and in conventional designs, the source and drain terminals flank the gate terminal A conducting channel is formed between the source and drain terminals, which can be controlled using the gate terminal

The three terminals of the MOSFETs are connected to metal lines or metal layers in order to form interconnections with other components of an integrated circuit. The connections between the three terminals and corresponding metal lines, such as, M1 (or level 1 or metal-1) metal lines presents challenges. The connections between the source and drain terminals and the metal line to which they connect, require a different height than the connection between the gate terminal and a corresponding metal line. Accordingly, separate processes are used; a first process is used for forming the metal connections to the source and drain, and a second process is used for forming the metal connections to the gate. This separate or second process for forming the metal connection or contact between a metal line and a gate terminal is difficult to control with high precision, and due to process variations and shrinking devices, the metal connection to the gate (or “metal-gate” connection) may develop imperfections such as being misaligned and/or suffer from variations in size or shape. Such imperfections may lead to undesirable short circuiting of the metal-gate connection with the metal connections to the source/drain.

Accordingly, there is a need in the art to overcome the drawbacks in conventional processes for forming metal-gate connections in transistors.

### SUMMARY

Exemplary embodiments are directed to a three-terminal semiconductor device including a self-aligned via for connecting to a gate terminal Hardmasks and spacers formed over top portions and sidewall portions of a drain connection to a drain terminal and a source connection to a source terminal protect and insulate the drain connection and the source connection, such that short circuits are avoided between the source and drain connections and the self-aligned via. The self-aligned via provides a direct metal-gate connection path between the gate terminal and a metal line such as a M1 metal line while avoiding a separate gate connection layer.

An exemplary embodiment is directed to a method of forming a three-terminal semiconductor device comprising: forming a drain connection to a drain terminal and a source connection to a source terminal; forming hardmasks over top portions of the drain connection and the source connection and spacers covering sidewall portions of the drain connection and the source connection, wherein the hardmasks and spacers have a first etch chemistry; filling a first dielectric layer around the hardmasks and spacers, wherein the first dielectric layer has a second etch chemistry; etching a via hole in the first dielectric layer to contact a gate terminal, using the second etch chemistry, such that the hardmasks and spacers are not affected by the second etch chemistry; and filling the via hole with a via material, such that the via material is prevented from short-circuits with the drain connection and the source connection, and wherein the via material provides a direct metal-gate connection path between the gate terminal and a metal line.

Another exemplary embodiment is directed to a semiconductor device comprising: a drain terminal; a source terminal; a drain connection to contact the drain terminal; a source connection to contact the source terminal; hardmasks formed over top portions of the drain connection and the source connection; spacers formed to cover sidewall portions of the drain connection and the source connection; and via material to provide a direct metal-gate connection path between the gate terminal and a metal line, wherein the via material is prevented from short-circuits with the drain connection and the source connection by the hardmasks and spacers.

Yet another exemplary embodiment is directed to a semiconductor device comprising: a drain terminal; a source terminal; a drain connection to contact the drain terminal; a source connection to contact the source terminal; means for protecting top portions and sidewall portions of the drain connection and the source connection; means for forming a direct metal-gate connection between the gate terminal and a second metal line, wherein the direct metal-gate connection is prevented from short-circuits with the drain connection and the source connection by the means for protecting.

### BRIEF DESCRIPTION OF THE DRAWINGS

The accompanying drawings are presented to aid in the description of embodiments of the invention and are provided solely for illustration of the embodiments and not limitation thereof

FIG. 1 illustrates a cross-sectional view of a conventional MOSFET device.

FIGS. 2A-K illustrate process steps related to formation of an exemplary three-terminal device with a self-aligned V0-PO contact.

FIG. 3 illustrates a flow-chart representation of a method of forming an exemplary three-terminal device with a self-aligned V0-PO contact.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Exemplary embodiments overcome the problems associated with conventional processes for forming contacts to transistor terminals. More specifically, with regard to three-terminal devices such as MOSFETs (including NMOS and PMOS), exemplary embodiments include processes for forming contacts between metal lines and gate terminals (or metal-gate connections or meta-gate connection paths), which are self-aligned. The exemplary self-aligned metal-gate connections are precisely aligned to avoid dangers of short circuits with metal connections to the drain and source terminals of the exemplary three-terminal devices. The exemplary self-aligned metal-gate connections are robust to process variations and are designed to prevent undesirable short-circuits between the metal-gate connections and the metal connections to the source/drain terminals. While embodiments are generally described with regard to MOSFET devices, it will be understood that such descriptions are merely illustrative; the processes and techniques described herein may be extended to any three-terminal transistor device without departing from the scope of the exemplary embodiments.

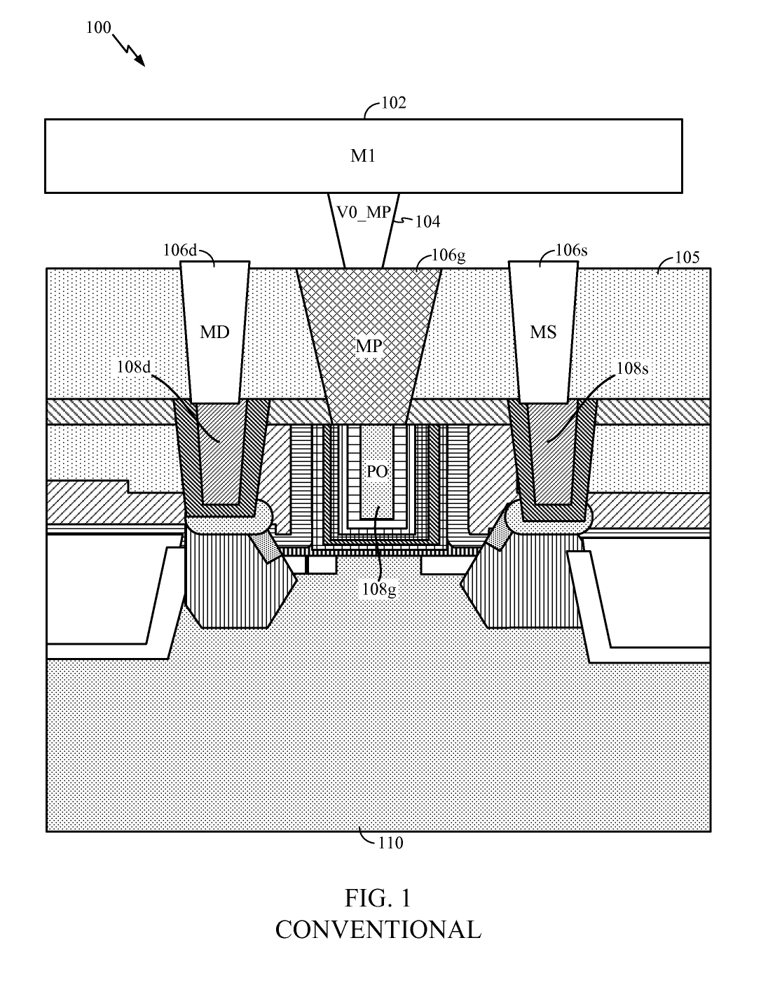

With reference to FIG. 1, a cross-sectional view of a conventional three-terminal transistor device 100 is illustrated. Device 100 may be formed on substrate 110, and may include the three terminals formed in the wells illustrated: drain terminal 108d, gate terminal 108g, and source terminal 108s. The gate terminal, conventionally formed from poly-silicon is also referred to as “poly” or “PO” herein. Drain and source contacts MD 106d and MS 106s are formed from drain and source terminals 108d and 108s respectively, to metal connections (not shown). Drain and source contacts MD 106d and MS 106s are formed by a first process, and dielectric material 105 is filled around MD 106d and MS 106s. Metal-gate connections require a separate process because the heights of drain and source terminals 108d and 108s are similar, but differ significantly from the height of gate terminal 108g.

The metal-gate connection is formed by a second or separate process, and involves the formation of a metal connection to poly, illustrated as MP 106g formed in dielectric layer 105, followed by the formation of via V0-MP 104 to connect MP 106g to a metal line shown as M1 102. However, as previously noted, with shrinking device sizes and various process variations which can occur, it is extremely difficult to control the shape and alignment of MP 106g, for example. As a result, the process of formation of MP 106g in dielectric 105 may result in imprecise etching and filling of material for MP 106g, which may lead to the placement of MP 106g being misaligned and/or the width of MP 106g becoming larger than desired. Misalignment and enlargement of the width of MP 106g can lead to short-circuit formation between MP 106g and MD 106d and/or MS 106s. Moreover, precisely controlling the formation of via V0-MP 104 is also difficult, and via V0-MP 104 may not land correctly on MP 106g to form the desired metal-gate connection between PO or gate terminal 108g and metal line M1 102.

Exemplary embodiments will now be described with regard to a step-by-step formation of a self-aligned via for a metal-gate connection with reference to the following figures. It will be understood that the process steps illustrated in these figures are not to be construed as a limitation, and as such, one or more process steps may be omitted and/or rearranged in order and/or further process steps may be added as will be understood by one skilled in the art, without departing from the scope of the embodiments disclosed herein.

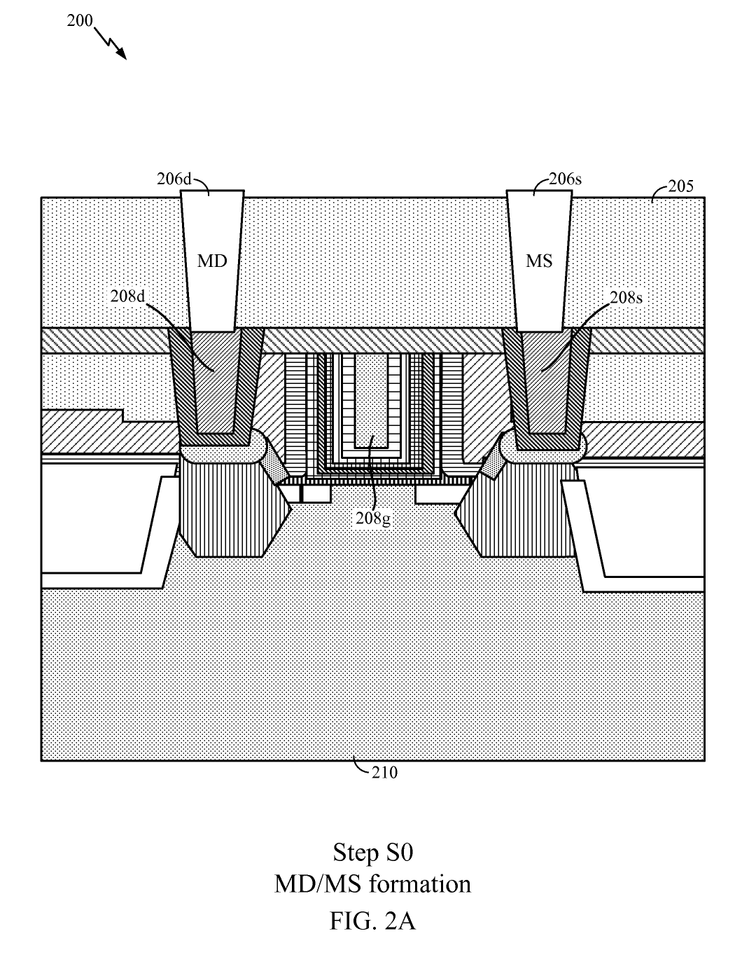

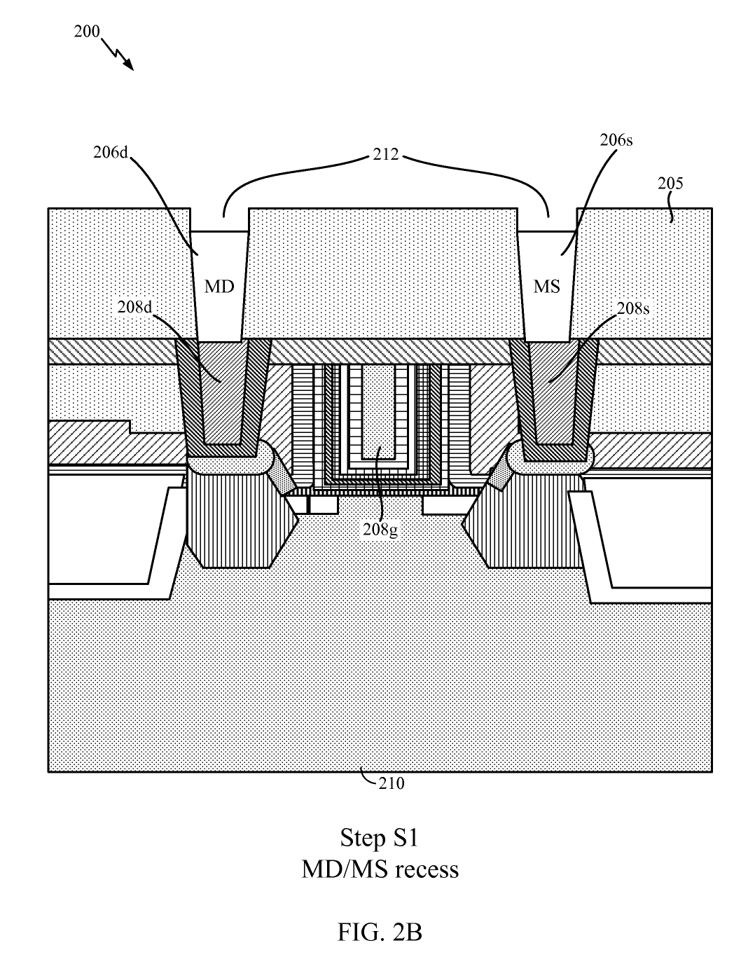

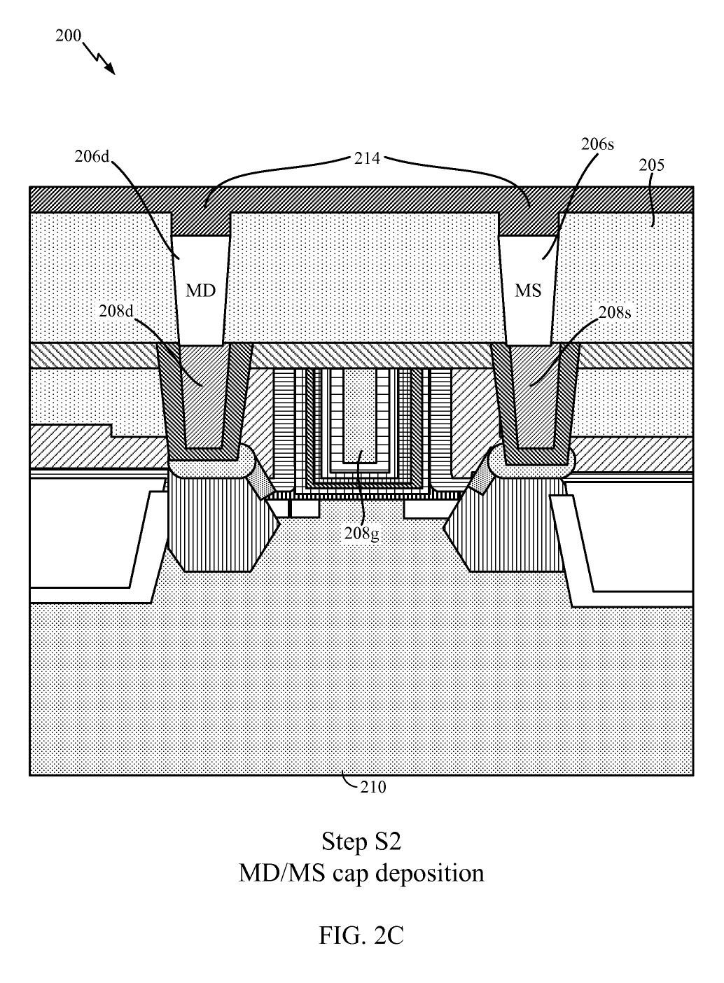

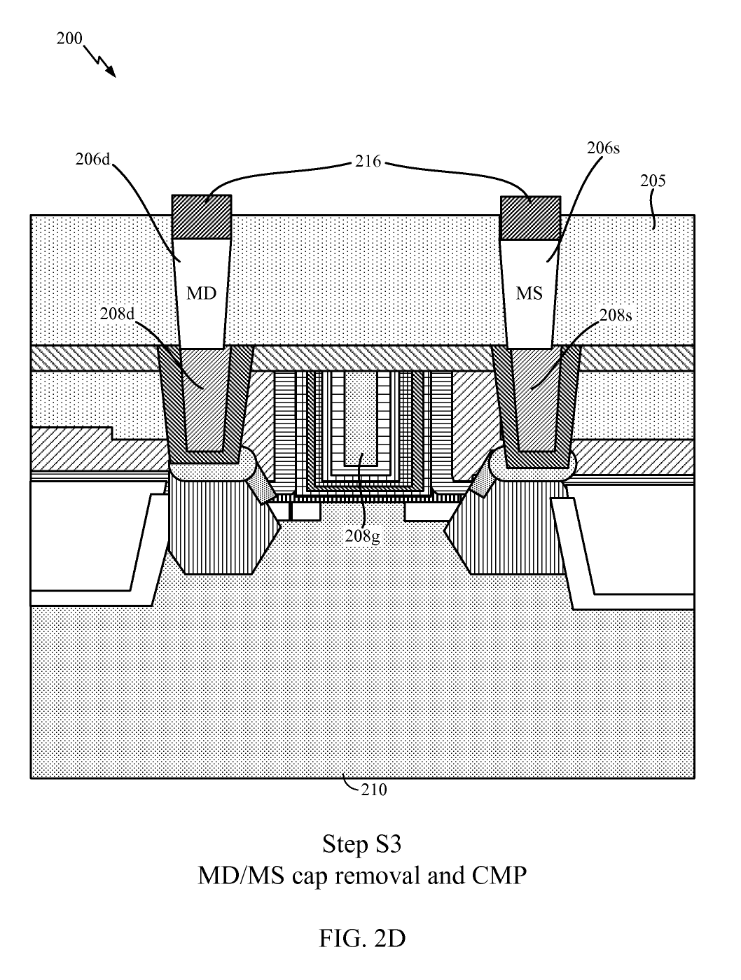

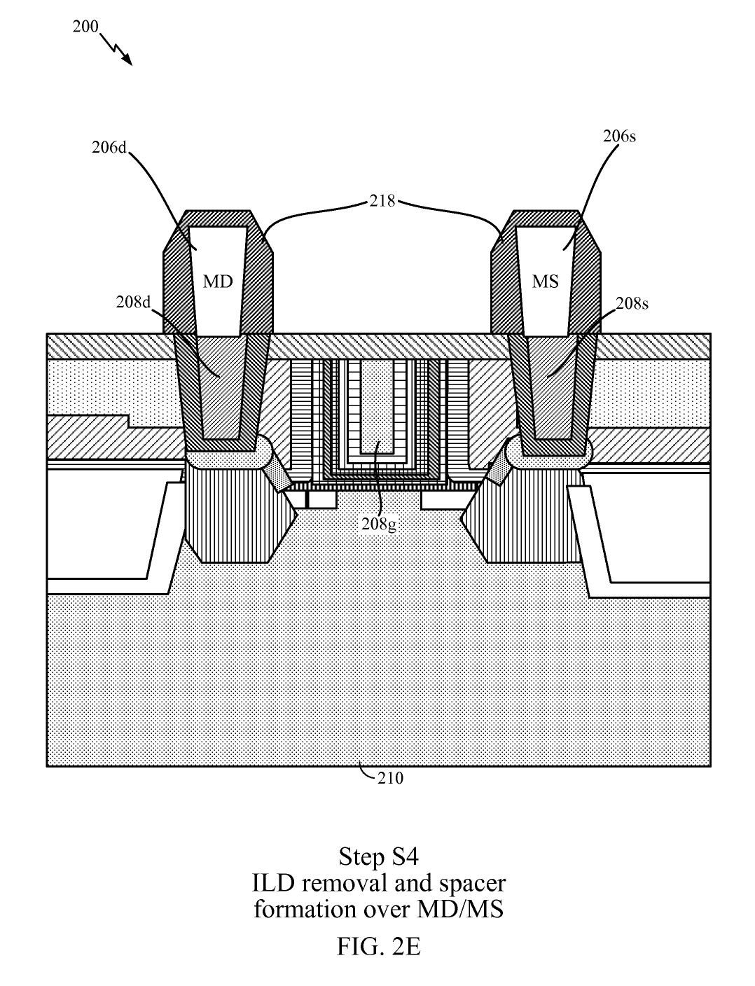

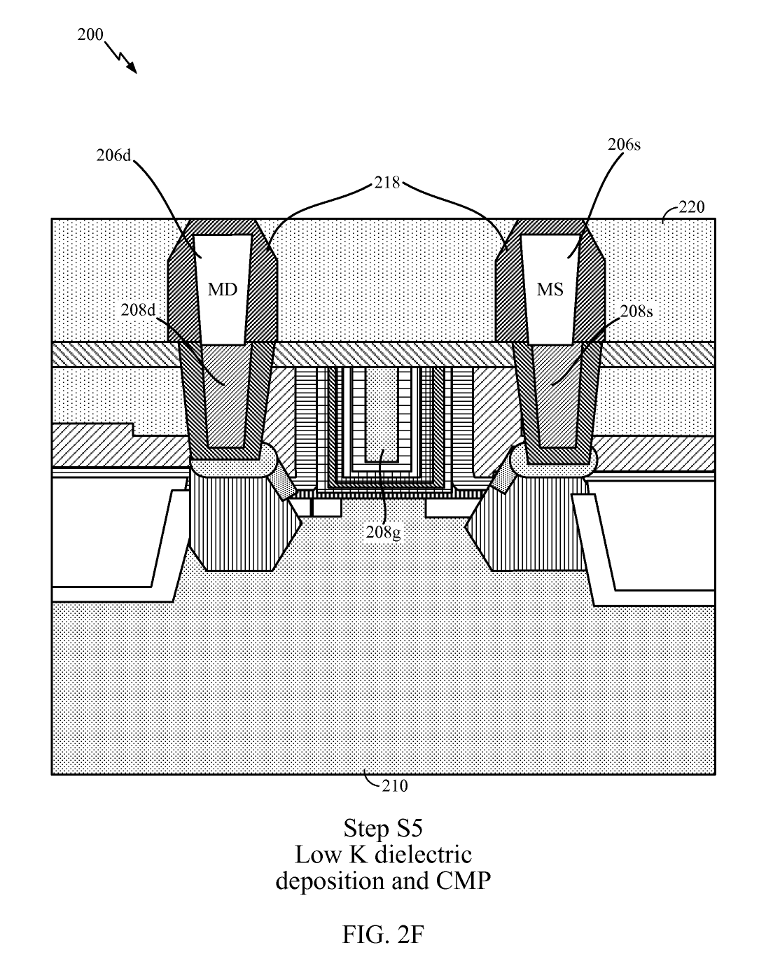

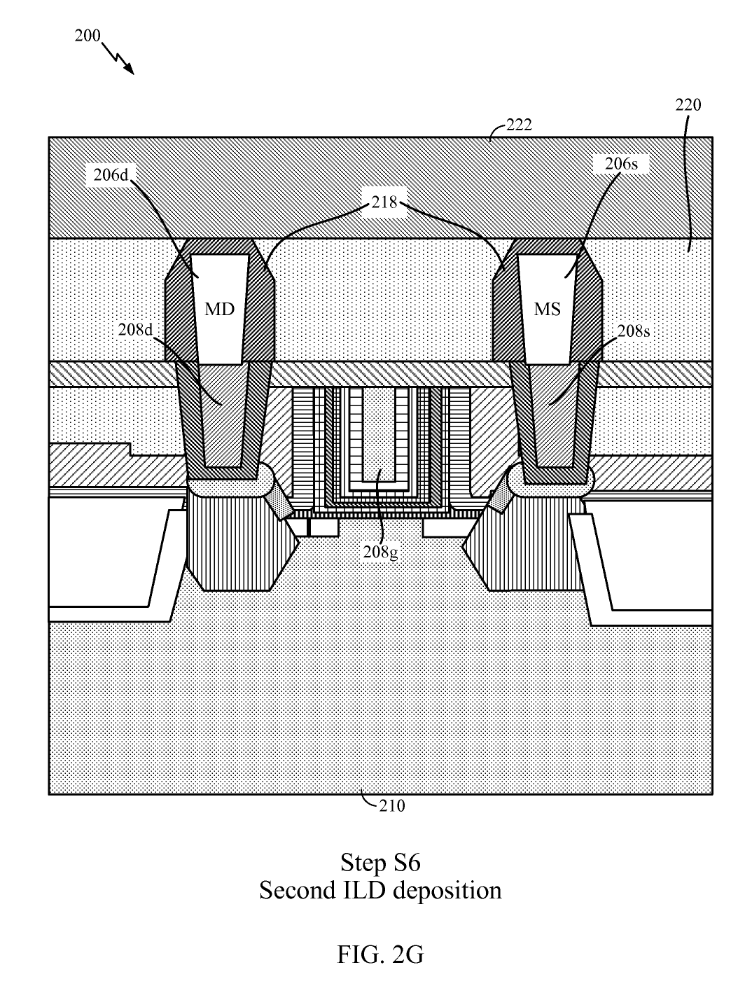

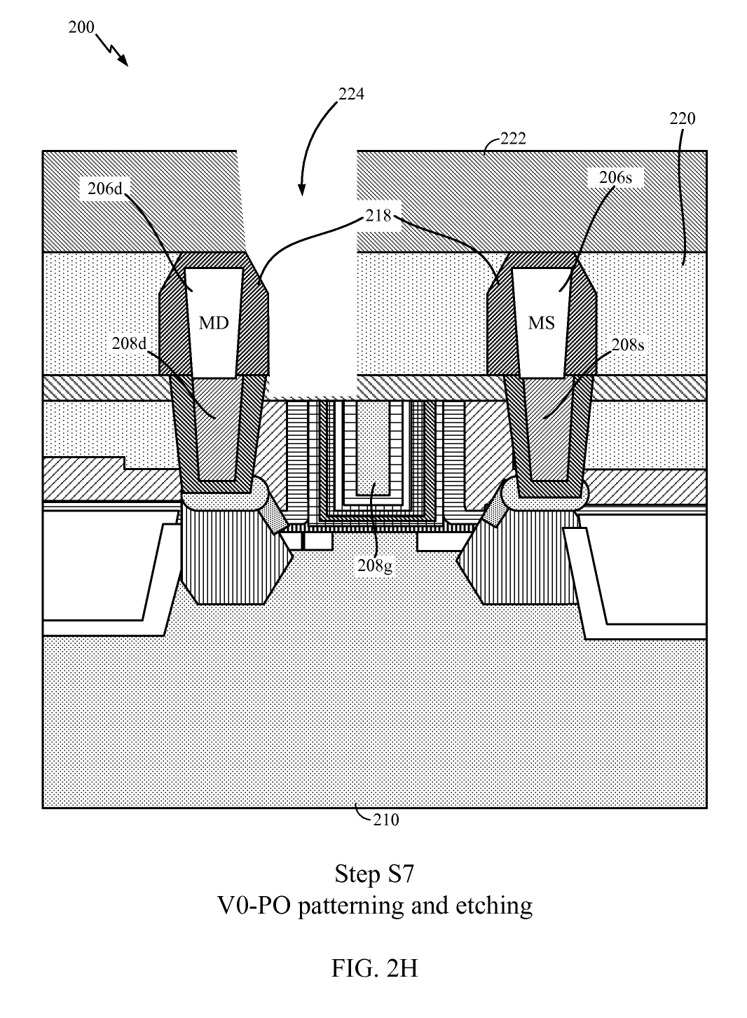

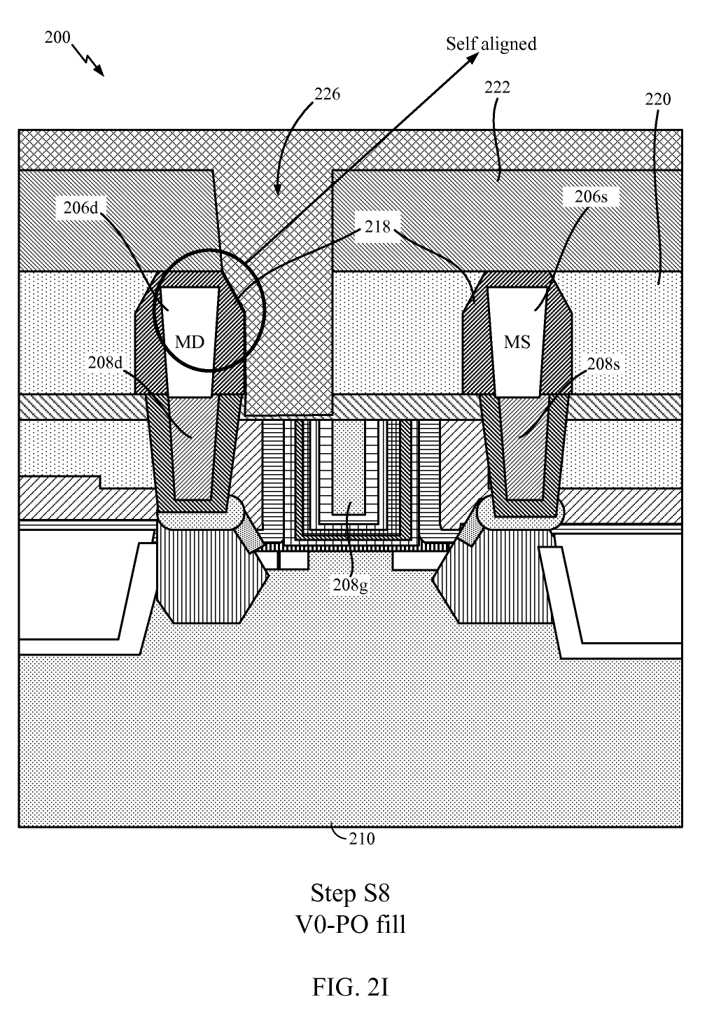

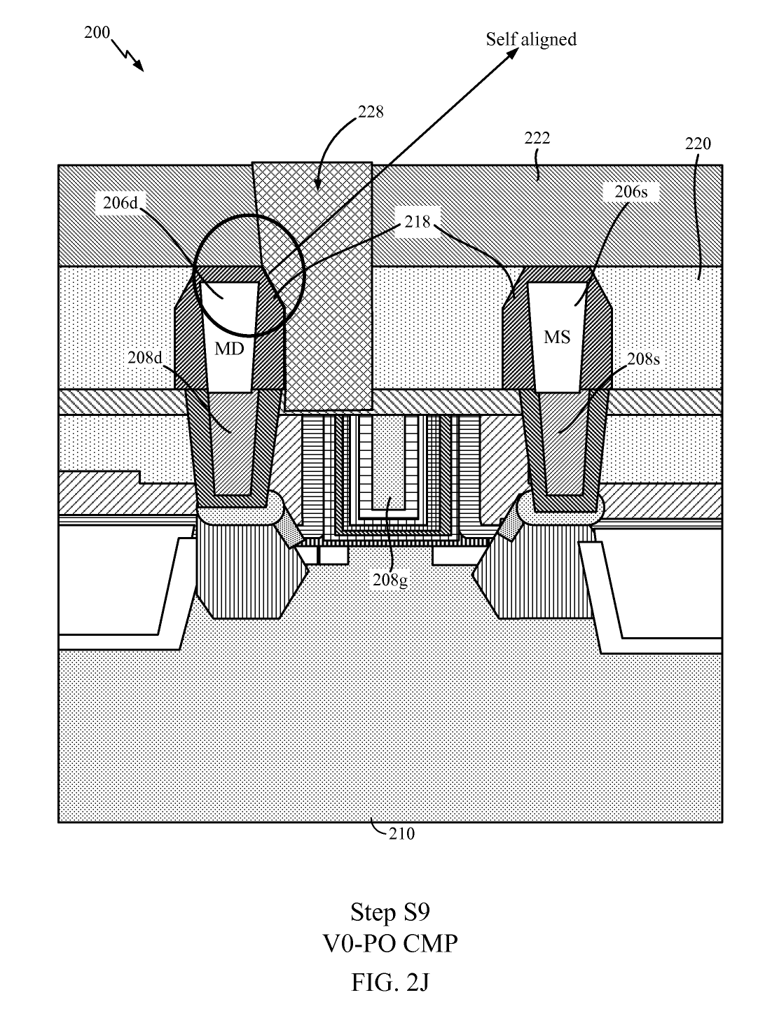

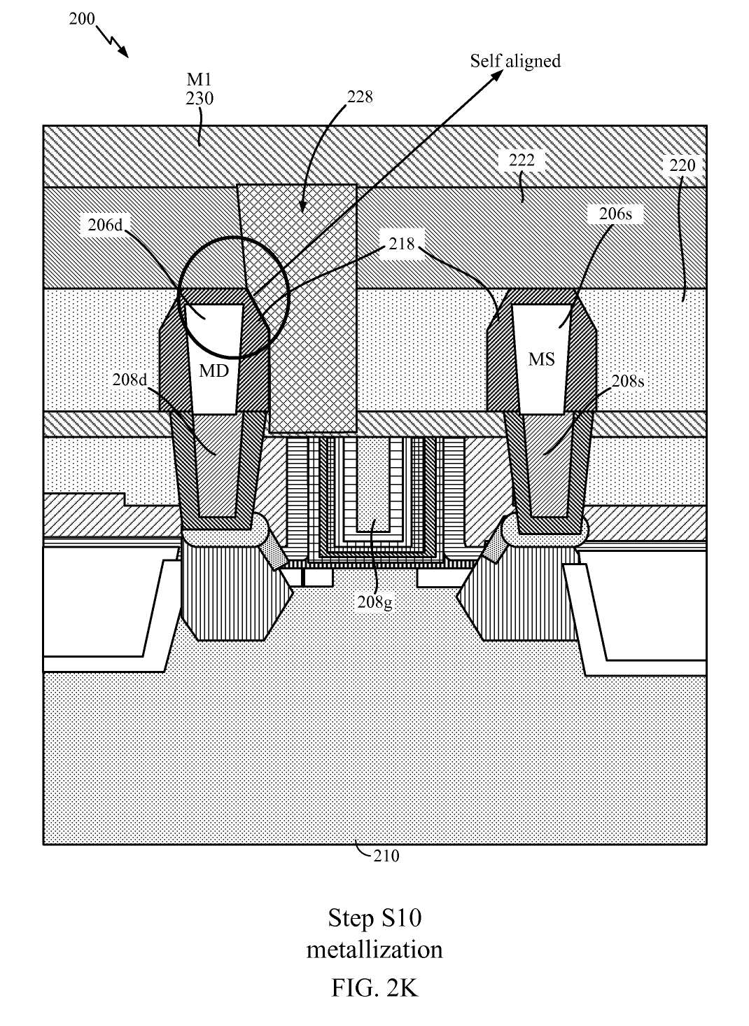

With reference first FIG. 2A, step SO related to formation of MD/MS contacts is illustrated. In more detail, FIG. 2A illustrates a schematic cross-sectional view of a process step in the formation of an exemplary three-terminal device 200, wherein device 200 may be a MOSFET in some embodiments. As such, step SO may be similar to conventional processes, and may include the formation of a substrate 210; deposition of materials for forming drain and source terminals 208d and 208s; deposition of poly-silicon or other suitable material for formation of gate terminal 208g; and formation of vias or contacts MD 206d and MS 206s in dielectric layer 205. Contacts MD 206d and MS 206s may be metallic and connect drain and source terminals 208d and 208s respectively to metal connections (not shown). Further process steps S1-S9 illustrated in FIGS. 2B-J depart from conventional processes, as will be explained in detail below.

Referring to FIG. 2B, step 51 is illustrated, where the MD/MS contacts (particularly their top portions) are recessed. More specifically, recesses are formed (e.g., in the order of 5 nm) by etching the metallic material from the top portions 212 of contacts MD 206d and MS 206s, as shown.

With reference to FIG. 2C, step S2 is illustrated where a cap layer 214 is deposited to fill the recesses 212 of FIG. 2B. Cap layer 214 may extend for a small height above all portions of dielectric layer 205, above and beyond filling the recesses 212, as shown. Cap layer 214 may be formed by depositing a hardmask material or insulating layer which protects MD 206d and MS 206s. The hardmask material forming cap layer 214 may include a material which has etch selectivity to dielectric layer 205, in order to enable selecting etching away of cap layer 214 and precisely stopping at etch layer 205, as will be discussed in step S3 below.

In FIG. 2D, step S3 is illustrated where cap layer 214 is removed, for example, by selective etching, except for hardmasks 216 remaining over MD 206d and MS 206s, as shown. Chemical mechanical polishing (CMP) may be performed to precisely retain the material in hardmasks 216, while removing the hardmask material from the top of the remaining portions of dielectric layer 205.

With reference to FIG. 2E, step S4 is shown, wherein, by switching etching chemistry, the dielectric layer 205 is removed and spacers 218 are formed to surround sidewalls of MD 206d and MS 206s as shown. Spacers 218 may be formed from insulating materials, and may be of similar material as hardmasks 216 of FIG. 2D. Spacers 218 and hardmasks 216 protect MD 206d and MS 206s from undesirable short circuits.

In FIG. 2F, step S5 is illustrated, where a low K dielectric 220 is filled around spacers 218 and hardmasks 216. Once again, CMP may be performed after filling low K dielectric 220.

Coming now to FIG. 2G, step S6 is illustrated where a second ILD layer 222 is deposited on top of low K dielectric 220 and hardmasks 216.

In FIG. 2H, step S7 is illustrated where patterning is performed for a self-aligned via according to exemplary embodiments. Etching is performed to create via hole 224 through the second ILD layer 222 and low K dielectric 220. Spacers 218 and hardmasks 216 are prevented from being etched, and they remain as protective covers over MD 206d and MS 206s. The via hole 224 lands on PO or gate terminal 208g. The landing of via hole 224 on gate terminal 208g has been intentionally illustrated as off-centered from the gate terminal 208g, and aligned closer to MD 206d, in order to demonstrate process variations which may take place, and prevent precise etching and patterning of via hole 224 to be perfectly centered with gate terminal 208g. This illustration conveys the beneficial aspects of embodiments, wherein, even though via hole 224 is off-centered, there will be no danger of shorting between any metallic material which will be subsequently filled in via hole 224 and MD 206d due to protective spacer 218 and hardmask 216 formed around MD 206d.

With reference to FIG. 21, step S8 is illustrated where via material 226 (e.g., a metallic or conductive material) is filled in via hole 224 of FIG. 2H. As seen, via material 226 is aligned with respect to MD 206d, in the sense that MD 206d is protected from making electrical contact with via material 226 due to insulating capping layer 218. Via material 226 is also aligned to ensure that a contact is formed with the PO or gate material 208g. In this disclosure, these aspects of alignment of via material 226 are referred to as self-aligned.” More specifically, via material 226 is self-aligned by use of insulating cap layer 218 to avoid undesirable shorting with MD 206d and also to ensure that a contact is formed with gate material 208g. In some aspects, the self-alignment may be additionally or alternatively described with relationship to MS 206s, which is also protected by insulating cap layer 218. It is also seen that via material 226 may be filled above and beyond second ILD layer 222, which can be adjusted in step S9 below. In exemplary embodiments, via material 226 may comprise one or more of tungsten, copper, titanium, or a combination thereof.

With reference to FIG. 2J, step S9 is illustrated where CMP is performed to remove excess via material 226 from over the unwanted regions on top of second ILD layer 222, to form the precisely self-aligned via 228. Via 228 is also referred to as a “Via 0” in the art, because it can be used to contact metal layer M1 (not shown). As such, due to connection with the gate terminal 208g or PO, via 228 is also referred to as V0-PO, consistent with terminology commonly employed in the art.

With reference to FIG. 2K, step S10 is illustrated, where, similar to metal line M1 102 of FIG. 1, a metal line, M1 230 can be formed over via 228 and second ILD layer 222 as shown, such that via 228 or V0-PO may directly contact gate terminal 208g with metal line M1 230.

It is observed that this direct contact of the exemplary V0-PO via 228 diverges from conventional implementations of device 100 of FIG. 1, where a two-step metal-gate connection is formed between metal line 102 and gate terminal 108g, comprising MP 106g and V0-MP 104. The exemplary V0-PO via 228 excludes a separate gate connection layer such as MP 106g. Exemplary V0-PO via 228, formed for example, from exemplary processes described above is self-aligned, and does not suffer from the deficiencies of the conventional two step metal-gate connections. It is noted that V0 vias may also be required for connecting MD 106d and MS 106s to their respective metal connections (not explicitly illustrated). These V0 vias for MD 106d and MS 106s connections to their respective metal lines can be easily formed of different heights than the V0-PO via 228 according to processes described above.

Accordingly, the exemplary V0-PO structures can advantageously scale down with shrinking device sizes, and require less space between exemplary MD and MS contacts to drain and source terminals of three-terminal devices. This promotes flexible design solutions in scaled down device sizes.

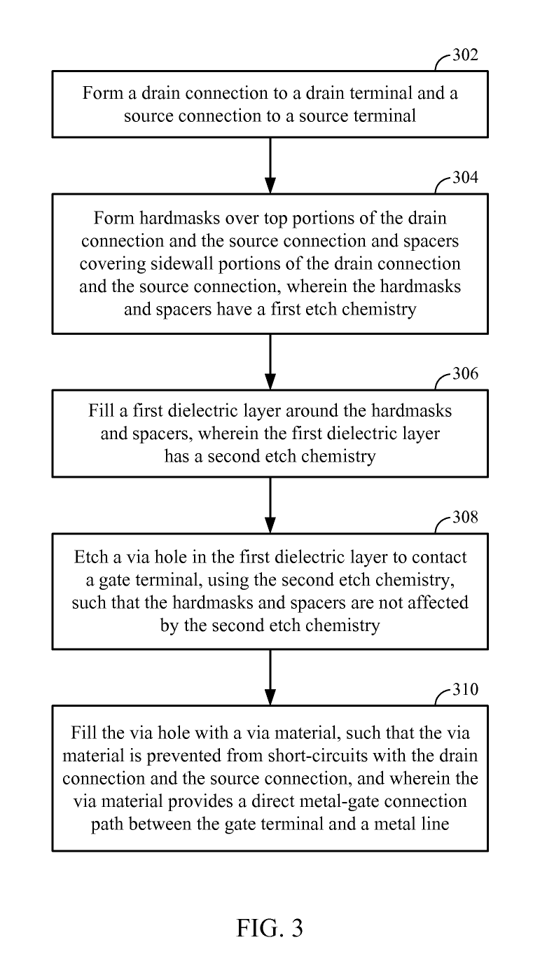

It will be appreciated that embodiments include various methods for performing the processes, functions and/or algorithms disclosed herein. For example, as illustrated in FIG. 3, an embodiment can include a method of forming a three-terminal semiconductor device (e.g., device 200) comprising: forming a drain connection (e.g., MD 206d) to a drain terminal (e.g., 208d) and a source connection (e.g., MS 206s) to a source terminal (e.g., 208s)—Block 302; forming hardmasks (e.g., 216) over top portions of the drain connection and the source connection and spacers (e.g., 218) covering sidewall portions of the drain connection and the source connection, wherein the hardmasks and spacers have a first etch chemistry—Block 304; filling a first dielectric layer (e.g., low K dielectric 220) around the hardmasks and spacers, wherein the first dielectric layer has a second etch chemistry—Block 306; etching a via hole (e.g., 224) in the first dielectric layer to contact a gate terminal (e.g., 208g), using the second etch chemistry, such that the hardmasks and spacers are not affected by the second etch chemistry—Block 308; filling the via hole with a via material (e.g., 226/228), such that the via material is prevented from short-circuits with the drain connection and the source connection, and wherein the via material provides a direct metal-gate connection path between the gate terminal and a metal line (e.g., M1 230)—Block 310.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. Further, the foregoing disclosed devices and methods may be designed and are configured into GDSII and GERBER computer files, stored on a computer readable media. These files are in turn provided to fabrication handlers who fabricate devices based on these files. The resulting products are semiconductor wafers that are then cut into semiconductor die and packaged into a semiconductor chip. The chips are then employed in devices described above.

Accordingly, an embodiment of the invention can include a computer readable media embodying a method for forming a three-terminal semiconductor device with a self-aligned metal-gate connection or V0-PO contact. Accordingly, the invention is not limited to illustrated examples and any means for performing the functionality described herein are included in embodiments of the invention. Further, the exemplary semiconductor device can be integrated in at least one semiconductor die. The exemplary semiconductor device may also be integrated in a device selected from the group consisting of a set top box, music player, video player, entertainment unit, navigation device, communications device, personal digital assistant (PDA), fixed location data unit, and a computer.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method of forming a three-terminal semiconductor device comprising:
forming a drain connection to a drain terminal and a source connection to a source terminal;
forming hardmasks over top portions of the drain connection and the source connection and spacers covering sidewall portions of the drain connection and the source connection, wherein the hardmasks and spacers have a first etch chemistry;
filling a first dielectric layer around the hardmasks and spacers, wherein the first dielectric layer has a second etch chemistry;
etching a via hole in the first dielectric layer to contact a gate terminal, using the second etch chemistry, such that the hardmasks and spacers are not affected by the second etch chemistry; and
filling the via hole with a via material, such that the via material is prevented from short-circuits with the drain connection and the source connection, and wherein the via material provides a direct metal-gate connection path between the gate terminal and a metal line.

2. The method of claim 1, wherein the direct metal-gate connection path is self-aligned with respect to the source connection, and the drain connection.

3. The method of claim 1, wherein forming the hardmasks comprises forming a recess over a top portion of the source connection and the drain connection, depositing a hardmask material in the recessed portion and performing chemical mechanical polishing.

4. The method of claim 1, wherein a height of the via material that provides the direct metal-gate connection path is different from heights of the source connection and the drain connection.

5. The method of claim 1, wherein the three-terminal semiconductor device is a metal-oxide semiconductor field effect transistor (MOSFET).

6. The method of claim 5, wherein the MOSFET is one an n-channel MOSFET (NMOS) or a p-channel MOSFET (PMOS).

7. The method of claim 1, wherein the via material comprises one or more of tungsten, copper, titanium, or a combination thereof.

8. The method of claim 1, wherein the metal line is a metal-1 or M1 metal line, and the direct metal-gate connection path provided by the via material excludes a separate gate connection layer between the gate terminal and the M1 metal line.

9. A semiconductor device comprising:
a drain terminal;
a source terminal;
a drain connection to contact the drain terminal;
a source connection to contact the source terminal;
hardmasks formed over top portions of the drain connection and the source connection;
spacers formed to cover sidewall portions of the drain connection and the source connection; and
via material to provide a direct metal-gate connection path between the gate terminal and a metal line, wherein the via material is prevented from short-circuits with the drain connection and the source connection by the hardmasks and spacers.

10. The semiconductor device of claim 9, wherein the direct metal-gate connection path is self-aligned with respect to the source connection, and the drain connection.

11. The semiconductor device of claim 9, wherein a height of the via material providing the direct metal-gate connection path is different from heights of the source connection and the drain connection.

12. The semiconductor device of claim 9, configured as a metal-oxide semiconductor field-effect transistor (MOSFET).

13. The semiconductor device of claim 9, wherein the via material comprises one or more of tungsten, copper, titanium, or a combination thereof.

14. The semiconductor device of claim 9, wherein the metal line is a metal-1 or M1 metal line, and the direct metal-gate connection path provided by the via material is configured to exclude a separate gate connection layer between the gate terminal and the M1 metal line.

15. The semiconductor device of claim 9 integrated in at least one semiconductor die.

16. The semiconductor device of claim 9 integrated in a device selected from the group consisting of a set top box, music player, video player, entertainment unit, navigation device, communications device, personal digital assistant (PDA), fixed location data unit, and a computer.

17. A semiconductor device comprising:
a drain terminal;
a source terminal;
a drain connection to contact the drain terminal;
a source connection to contact the source terminal;
means for protecting top portions and sidewall portions of the drain connection and the source connection; and
means for forming a direct metal-gate connection between the gate terminal and a second metal line, wherein the direct metal-gate connection is prevented from short-circuits with the drain connection and the source connection by the means for protecting.

18. The semiconductor device of claim 15, wherein the direct metal-gate connection path is self-aligned with respect to the source connection, and the drain connection.

19. The semiconductor device of claim 15, wherein a height of the direct metal-gate connection path is different from heights of the source connection and the drain connection.
